(19) United States
(12) Patent Application Publication
(10) Pub. No.: US 2026/0120774 A1
(43) Pub. Date: Apr. 30, 2026

(54) ANALOG MULTIPLY AND ACCUMULATE ARCHITECTURE FOR COMPUTE-IN-MEMORY MACHINE LEARNING

(71) Applicant: Micron Technology, Inc., Boise, ID (US)

(72) Inventor: Tomoharu Tanaka, Yokohama (JP)

(21) Appl. No.: 19/353,955

(22) Filed: Oct. 9, 2025

Related U.S. Application Data
(60) Provisional application No. 63/713,681, filed on Oct. 30, 2024.

(51) Int. Cl. G11C 16/26; G11C 5/14; G11C 16/04; G11C 16/24; G11C 16/30

(52) U.S. Cl. CPC G11C 16/26; G11C 5/147; G11C 16/0433; G11C 16/24; G11C 16/30

(57) ABSTRACT

A memory device includes a sub-block with strings and a local bitline. A gate of a sense transistor is coupled with the local bitline. Control transistors provide a data read path between a read source line and the sense transistor and between the sense transistor and a global bitline. The device includes boost transistors, each coupled between the local bitline and a respective string. Control logic causes a voltage to be applied to a wordline associated with a first memory cell of a string and to a boost wordline to pull local bitline up and causes a bitline voltage, which represents a digital value, to be applied to global bitline. Control logic causes a current to be read out through the read source line from the first memory cell. An amount of the current depends on the digital value and represents an analog multiplier of a multiply and accumulate calculation.

### CLAIM OF PRIORITY

The present application claims the benefit under 35 U.S.C. § 119(e) of U.S. Provisional Patent Application No. 63/713,681 filed Oct. 30, 2024, which is incorporated by reference herein.

### TECHNICAL FIELD

Embodiments of the disclosure are generally related to memory sub-systems, and more specifically, relate to analog multiply and accumulate architecture for compute-in-memory machine learning.

### BACKGROUND

A memory sub-system can include one or more memory devices that store data. The memory devices can be, for example, non-volatile memory devices and volatile memory devices. In general, a host system can utilize a memory sub-system to store data at the memory devices and to retrieve data from the memory devices.

### BRIEF DESCRIPTION OF THE DRAWINGS

The present disclosure will be understood more fully from the detailed description given below and from the accompanying drawings of some embodiments of the disclosure.

FIG. 1A illustrates an example computing system that includes a memory sub-system in accordance with some embodiments.

FIG. 1B is a block diagram of a memory device in communication with a memory sub-system controller of a memory sub-system according to an embodiment.

FIG. 2A-2B are schematics of portions of an array of memory cells as could be used in a memory of the type described with reference to FIG. 1B according to an embodiment.

FIG. 3A is a schematic diagram of a simplified example of compute-in-memory (CIM) architecture for multiply and accumulate (MAC) calculations according to some embodiments.

FIG. 3B is a schematic diagram of a deep learning neural network, hidden layers of which can employ the CIM architecture of FIG. 3A the according to some embodiments.

FIG. 4 is a partial schematic diagram of a portion of a memory device employing a CIM architecture that compensates for non-linearities caused by parasitic resistance, temperature change, and charge loss according to some embodiments.

FIG. 5A is a flow diagram of an example method of operating the memory device of FIG. 4 according to some embodiments.

FIG. 5B is a flow diagram of an example method of operating the memory device of FIG. 4 according to one or more varied embodiments.

FIG. 6 is a block diagram of an example computer system in which embodiments of the present disclosure can operate.

### DETAILED DESCRIPTION

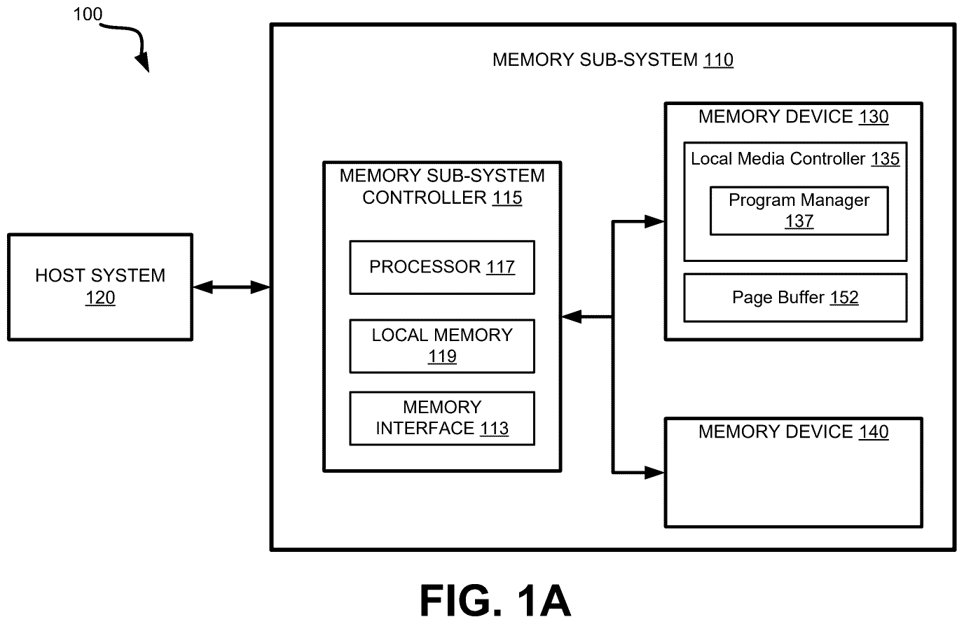

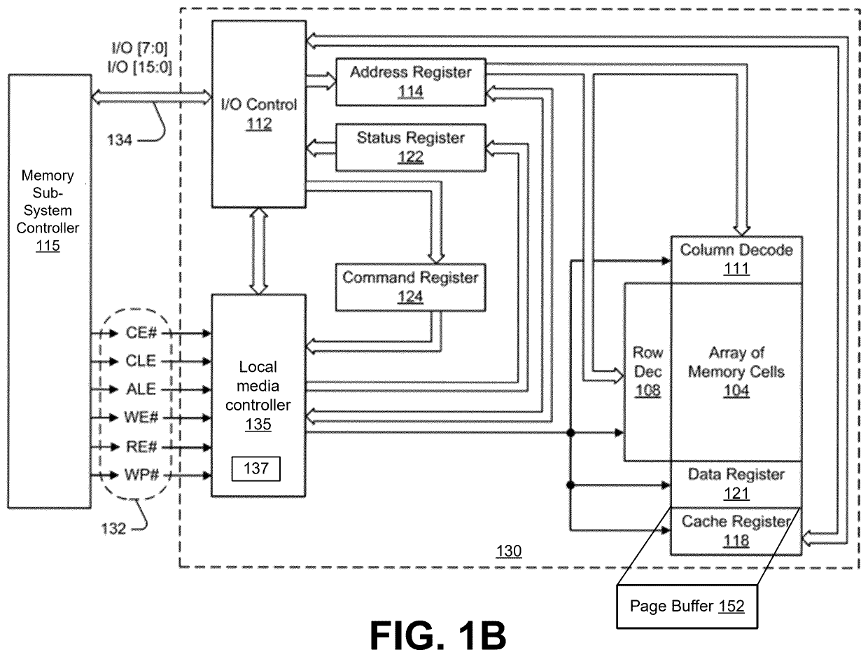

Embodiments of the present disclosure are directed to analog multiply and accumulate calculation (MAC) architecture for compute-in-memory (CIM) machine learning. One or more memory devices can be a part of a memory sub-system, which can be a storage device, a memory module, or a hybrid of a storage device and memory module. Examples of storage devices and memory modules are described below in conjunction with FIG. 1A. In general, a host system can utilize a memory sub-system that includes one or more components, such as memory devices that store data. The host system can provide data to be stored at the memory sub-system and can request data to be retrieved from the memory sub-system.

A memory sub-system can include high density non-volatile memory devices where retention of data is desired when no power is supplied to the memory device. One example of non-volatile memory devices is a NOT-and (NAND) memory device. Other examples of non-volatile memory devices are described below in conjunction with FIG. 1A. A non-volatile memory device is a package of one or more dies (or dice). Each die can include two or more planes. For some types of non-volatile memory devices (e.g., NAND devices), each plane includes of a set of physical blocks. In some implementations, each block can include multiple sub-blocks. Each plane carries a matrix of memory cells formed on a silicon wafer and joined by conductors referred to as wordlines (WLs) and bitlines (BLs), such that a wordline joins multiple memory cells forming a row of the matrix of memory cells, while a bitline joins multiple memory cells forming a column of the matrix of memory cells.

Depending on the cell type, each memory cell can store one or more bits of binary information, and has various logic states that correlate to the number of bits being stored. The logic states can be represented by binary values, such as “0” and “1,” or combinations of such values, also referred to herein as logical bit values. A memory cell can be programmed (written to) by applying a certain voltage to the memory cell, which results in an electric charge being held by the memory cell, thus allowing modulation of the voltage distributions produced by the memory cell. A set of memory cells referred to as a memory page can be programmed together in a single operation, e.g., by selecting consecutive bitlines. Precisely controlling the amount of the electric charge stored by the memory cell allows establishing multiple logical levels, thus effectively allowing a single memory cell to store multiple bits of information. A read operation can be performed by comparing the measured threshold voltages (Vₜ) exhibited by the memory cell to one or more reference voltage levels in order to distinguish between two logical levels for single-level cell (SLCs) and between multiple logical levels for multi-level cells.

In certain memory devices, memory arrays are built in three-dimensional (3D), multi-layered structures with memory cells coupled to pillars that form strings of transistors, which in turn make up memory arrays. Each pillar is coupled to a local bitline via an individual select gate controllable by a drain select line (SGD) signal. These types of memory devices can also be employed to perform a MAC calculation, which can be expressed as ΣGijVi, by way of a CIM architecture that leverages the matrix-like structure of WLs and BLs to perform mathematical operations in memory. While, in theory, performing machine learning (ML) and other artificial intelligence (AI) using CIM architectures can save significant power over doing so in software, practically carrying out ML/AI as compute-in-memory involves significant challenges.

For example, within a memory array, a difference between a voltage applied to WLs and threshold voltages of selected memory cells can represent Gij while corresponding BL voltages can represent Vi. A MAC calculation can be performed by reading out these GijVi values in the form of memory cell current (Icell) from different strings and then accumulated. Such MAC calculations can be embedded within hidden layers of a neural network (NN) in order to update NN learning and perform inferencing over time. For example, the NN can represent a machine learning model where the MAC values represent weights that are updated based on changes in inputs (e.g., WL voltages and/or BL voltages).

The challenge with this simple, matrix-like approach to MAC calculations in memory is that selected memory cells operate in a linear region. Thus, a drain voltage of a selected memory cells drops depending on where the memory cell is located within the string due to parasitic resistance of unselected memory cells. Further, threshold voltages of memory cells are temperature dependent, tend to change after programming because of charge loss, and shift depending on the Vₜ levels of neighbor memory cells. As machine learning models are required to operate with increasing precision, these variations in (or dependence on) threshold voltages make CIM-based MAC calculations untenable for practical, modern ML/AI applications.

Aspects of the present disclosure address the above and other deficiencies through integrating boost transistors and control transistors within the string-based CIM architecture of memory arrays as will be explained. For example, a memory array can be designed to include multiple sub-blocks, each including a plurality of strings of memory cells, where “the multiply” is performed in a given sub-block and the accumulate (of the MAC) is performed across sub-blocks. For a given sub-block (discussed by way of example), a local bitline can be coupled with the plurality of strings and a sense transistor having a gate terminal coupled with the local bitline. The sense transistor can turn ON or OFF depending on a voltage potential level of the local bitline, which is a result of a read process of the selected memory cell within one of the strings. In some memory devices, the sense transistor transfers data from the memory cell to a page buffer through a global bitline using an all bitline (ABL) scheme, e.g., where all global bitlines are accessed at the same time. Thus, the MAC calculation can be performed relatively quickly and with significantly lower power than performing machine learning in software.

In various embodiments, the disclosed CIM architecture is designed with a series of transistors (e.g., control transistors) that can include a data read path positioned between a read source line and the sense transistor and between the sense transistor and a global bitline. The CIM architecture can further include a set of boost transistors, each coupled between the local bitline and a respective string of the plurality of strings.

In embodiments, control logic is coupled with the memory array, the series of transistors, the set of boost transistors, and the page buffer. The control logic may then cause a particular voltage to be applied to a wordline associated with a first memory cell of a string of the plurality of strings and to a boost wordline associated with the set of boost transistors to pull the local bitline up to approximately the particular voltage. The control logic can also cause a bitline voltage to be applied to the global bitline, where the bitline voltage represents a digital value, e.g., as a NN input for a ML model. The control logic causes a current to be read out through the read source line from the first memory cell. In embodiments, an amount of the current depends on the digital value and represents an analog multiplier of a MAC associated with a machine learning model, for example.

In such embodiments, by causing the sense transistor to instead operate in a linear region while the string transistors are pulled up to a high voltage to be fully ON, once the BL voltage stabilizes, the current through the memory string stops flowing, eliminating concerns about parasitic resistance in the memory string. In this way, reading the Vt out of the selected memory cell can be performed without fluctuating based on different parasitic resistance. As discussed, however, Vₜ can vary for other reasons such as temperature dependency, charge loss, and shifts due to Vₜ levels of neighboring memory cells. Compensation can be provided for these other types of Vₜ changes as an optimization integrated within the disclosed CIM architecture, as will be discussed in detail.

Further, in other embodiments, the transistors of the series of transistors that are coupled to the read source line and the global bitline have gate terminals coupled with a read-enable control line, and a first voltage applied to the read-enable control line can instead be varied while the global bitline voltage is maintained constant. In still other embodiments, the first voltage applied to the read-enable control line can also be held constant but applied for a varying period of time. In this way, by either varying the amount of the first voltage or the period of time the first voltage is applied to the read-enable control line, this disclosure provides additional ways to vary the digital values that will vary the amount of current to be associated with weights of ML/AI applications when the global bitline is held constant.

Therefore, advantages of the systems and methods implemented in accordance with some embodiments of the present disclosure include employing fast, yet power-conserving, MAC calculations with a CIM architecture that is designed for precision despite being designed with memory arrays that have inherent challenges with process and parasitic resistance variations. The precision, for example, can be a result of avoiding variations in threshold voltages of memory cells due to parasitic resistance that varies based on where within a memory string a selected memory cell is located. As will be further discussed, additional compensation can be designed within the disclosed CIM architecture to significantly reduce other variations in Vₜ of selected memory cells. Other advantages will be apparent to those skilled in the art of CIM hardware architecture, which will be discussed hereinafter.

FIG. 1A illustrates an example computing system 100 that includes a memory sub-system 110 in accordance with some embodiments of the present disclosure. The memory sub-system 110 can include media, such as one or more volatile memory devices (e.g., memory device 140), one or more non-volatile memory devices (e.g., memory device 130), or a combination of such media or memory devices.

A memory sub-system 110 can be a storage device, a memory module, or a combination of a storage device and memory module. Examples of a storage device include a solid-state drive (SSD), a flash drive, a universal serial bus (USB) flash drive, an embedded Multi-Media Controller (eMMC) drive, a Universal Flash Storage (UFS) drive, a secure digital (SD) card, and a hard disk drive (HDD). Examples of memory modules include a dual in-line memory module (DIMM), a small outline DIMM (SO-DIMM), and various types of non-volatile dual in-line memory modules (NVDIMMs).

The computing system 100 can be a computing device such as a desktop computer, laptop computer, network server, mobile device, a vehicle (e.g., airplane, drone, train, automobile, or other conveyance), Internet of Things (IoT) enabled device, embedded computer (e.g., one included in a vehicle, industrial equipment, or a networked commercial device), or such computing device that includes memory and a processing device.

The computing system 100 can include a host system 120 that is coupled to one or more memory sub-systems 110. In some embodiments, the host system 120 is coupled to multiple memory sub-systems 110 of different types. FIG. 1A illustrates one example of a host system 120 coupled to one memory sub-system 110. The host system 120 can provide data to be stored at the memory sub-system 110 and can request data to be retrieved from the memory sub-system 110. As used herein, “coupled to” or “coupled with” generally refers to a connection between components, which can be an indirect communicative connection or direct communicative connection (e.g., without intervening components), whether wired or wireless, including connections such as electrical, optical, magnetic, etc.

The host system 120 can include a processor chipset and a software stack executed by the processor chipset. The processor chipset can include one or more cores, one or more caches, a memory controller (e.g., NVDIMM controller), and a storage protocol controller (e.g., PCIe controller, SATA controller). The host system 120 uses the memory sub-system 110, for example, to write data to the memory sub-system 110 and read data from the memory sub-system 110.

The host system 120 can be coupled to the memory sub-system 110 via a physical host interface. Examples of a physical host interface include, but are not limited to, a serial advanced technology attachment (SATA) interface, a peripheral component interconnect express (PCIe) interface, universal serial bus (USB) interface, Fibre Channel, Serial Attached SCSI (SAS), a double data rate (DDR) memory bus, Small Computer System Interface (SCSI), a dual in-line memory module (DIMM) interface (e.g., DIMM socket interface that supports Double Data Rate (DDR)), etc. The physical host interface can be used to transmit data between the host system 120 and the memory sub-system 110. The host system 120 can further utilize an NVM Express (NVMe) interface to access components (e.g., memory devices 130) when the memory sub-system 110 is coupled with the host system 120 by the physical host interface (e.g., PCIe bus). The physical host interface can provide an interface for passing control, address, data, and other signals between the memory sub-system 110 and the host system 120. FIG. 1A illustrates a memory sub-system 110 as an example. In general, the host system 120 can access multiple memory sub-systems via a same communication connection, multiple separate communication connections, and/or a combination of communication connections.

The memory devices 130, 140 can include any combination of the different types of non-volatile memory devices and/or volatile memory devices. The volatile memory devices (e.g., memory device 140) can be, but are not limited to, random access memory (RAM), such as dynamic random access memory (DRAM) and synchronous dynamic random access memory (SDRAM).

Some examples of non-volatile memory devices (e.g., memory device 130) include a NOT-and (NAND) type flash memory and write-in-place memory, such as a three-dimensional cross-point (“3D cross-point”) memory device, which is a cross-point array of non-volatile memory cells. A cross-point array of non-volatile memory cells can perform bit storage based on a change of bulk resistance, in conjunction with a stackable cross-gridded data access array. Additionally, in contrast to many flash-based memories, cross-point non-volatile memory can perform a write in-place operation, where a non-volatile memory cell can be programmed without the non-volatile memory cell being previously erased. NAND type flash memory includes, for example, two-dimensional NAND (2D NAND) and three-dimensional NAND (3D NAND).

Each of the memory devices 130 can include one or more arrays of memory cells. One type of memory cell, for example, single level cells (SLC) can store one bit per cell. Other types of memory cells, such as multi-level cells (MLCs), triple-level cells (TLCs), quad-level cells (QLCs), and penta-level cells (PLCs) can store multiple bits per cell. In some embodiments, each of the memory devices 130 can include one or more arrays of memory cells such as SLCs, MLCs, TLCs, QLCs, PLCs or any combination of such. In some embodiments, a particular memory device can include an SLC portion, and an MLC portion, a TLC portion, a QLC portion, or a PLC portion of memory cells. The memory cells of the memory devices 130 can be grouped as pages that can refer to a logical unit of the memory device used to store data. With some types of memory (e.g., NAND), pages can be grouped to form blocks.

Although non-volatile memory components such as a 3D cross-point array of non-volatile memory cells and NAND type flash memory (e.g., 2D NAND, 3D NAND) are described, the memory device 130 can be based on any other type of non-volatile memory, such as read-only memory (ROM), phase change memory (PCM), self-selecting memory, other chalcogenide based memories, ferroelectric transistor random-access memory (FeTRAM), ferroelectric random access memory (FeRAM), magneto random access memory (MRAM), Spin Transfer Torque (STT)-MRAM, conductive bridging RAM (CBRAM), resistive random access memory (RRAM), oxide based RRAM (OxRAM), NOT-or (NOR) flash memory, or electrically erasable programmable read-only memory (EEPROM).

A memory sub-system controller 115 (or controller 115 for simplicity) can communicate with the memory devices 130 to perform operations such as reading data, writing data, or erasing data at the memory devices 130 and other such operations. The memory sub-system controller 115 can include hardware such as one or more integrated circuits and/or discrete components, a buffer memory, or a combination thereof. The hardware can include a digital circuitry with dedicated (i.e., hard-coded) logic to perform the operations described herein. The memory sub-system controller 115 can be a microcontroller, special purpose logic circuitry (e.g., a field programmable gate array (FPGA), an application specific integrated circuit (ASIC), etc.), or other suitable processor.

The memory sub-system controller 115 can include a processing device, which includes one or more processors (e.g., processor 117), configured to execute instructions stored in a local memory 119. In the illustrated example, the local memory 119 of the memory sub-system controller 115 includes an embedded memory configured to store instructions for performing various processes, operations, logic flows, and routines that control operation of the memory sub-system 110, including handling communications between the memory sub-system 110 and the host system 120.

In some embodiments, the local memory 119 can include memory registers storing memory pointers, fetched data, etc. The local memory 119 can also include read-only memory (ROM) for storing micro-code. While the example memory sub-system 110 in FIG. 1A has been illustrated as including the memory sub-system controller 115, in another embodiment of the present disclosure, a memory sub-system 110 does not include a memory sub-system controller 115, and can instead rely upon external control (e.g., provided by an external host, or by a processor or controller separate from the memory sub-system).

In general, the memory sub-system controller 115 can receive commands or operations from the host system 120 and can convert the commands or operations into instructions or appropriate commands to achieve the desired access to the memory devices 130. The memory sub-system controller 115 can be responsible for other operations such as wear leveling operations, garbage collection operations, error detection and error-correcting code (ECC) operations, encryption operations, caching operations, and address translations between a logical address (e.g., a logical block address (LBA), namespace) and a physical address (e.g., physical block address) that are associated with the memory devices 130. The memory sub-system controller 115 can further include host interface circuitry to communicate with the host system 120 via the physical host interface. The host interface circuitry can convert the commands received from the host system into command instructions to access the memory devices 130 as well as convert responses associated with the memory devices 130 into information for the host system 120.

The memory sub-system 110 can also include additional circuitry or components that are not illustrated. In some embodiments, the memory sub-system 110 can include a cache or buffer (e.g., DRAM) and address circuitry (e.g., a row decoder and a column decoder) that can receive an address from the memory sub-system controller 115 and decode the address to access the memory devices 130.

In some embodiments, the memory devices 130 include local media controllers 135 that operate in conjunction with memory sub-system controller 115 to execute operations on one or more memory cells of the memory devices 130. An external controller (e.g., memory sub-system controller 115) can externally manage a memory device 130 (e.g., perform media management operations on the memory device 130). In some embodiments, memory sub-system 110 is a managed memory device, which is a raw memory device 130 having control logic (e.g., local media controller 135) on the die and a controller (e.g., memory sub-system controller 115) for media management within the same memory device package. An example of a managed memory device is a managed NAND (MNAND) device.

In one embodiment, the memory sub-system 110 includes a memory interface component 113. Memory interface component 113 is responsible for handling interactions of memory sub-system controller 115 with the memory devices of memory sub-system 110, such as memory device 130. For example, memory interface component 113 can send memory access commands corresponding to requests received from host system 120 to memory device 130, such as program commands, read commands, or other commands. In addition, memory interface component 113 can receive data from memory device 130, such as data retrieved in response to a read command or a confirmation that a program command was successfully performed. For example, the memory sub-system controller 115 can include a processor 117 (or processing device) configured to execute instructions stored in local memory 119 for performing the operations described herein.

In at least one embodiment, the memory device 130 includes a program manager 137 configured to carry out memory operations, e.g., in response to receiving memory access commands from the memory interface 113. In some implementations, the local media controller 135 includes at least a portion of the program manager 137 and is configured to perform the functionality described herein. In some implementations, the program manager 137 is implemented on the memory device 130 using firmware, hardware components, or a combination of the above. In some embodiments, control logic of the program manager 137 is integrated in whole or in part within the memory sub-system controller 115 and/or the host system 120. In some embodiments, the memory device 130 includes a page buffer 152, which can provide at least some of the circuitry used to program data to the memory cells of the memory device 130 and to read the data out of the memory cells.

FIG. 1B is a simplified block diagram of a first apparatus, in the form of a memory device 130, in communication with a second apparatus, in the form of a memory sub-system controller 115 of a memory sub-system (e.g., the memory sub-system 110 of FIG. 1A), according to an embodiment. Some examples of electronic systems include personal computers, personal digital assistants (PDAs), digital cameras, digital media players, digital recorders, games, appliances, vehicles, wireless devices, mobile telephones and the like. The memory sub-system controller 115 (e.g., a controller external to the memory device 130), can be a memory controller or other external host device.

The memory device 130 includes an array of memory cells 104 logically arranged in rows and columns. Memory cells of a logical row are typically connected to the same access line (e.g., a wordline) while memory cells of a logical column are typically selectively connected to the same data line (e.g., a bitline). A single access line can be associated with more than one logical row of memory cells and a single data line can be associated with more than one logical column. Memory cells (not shown in FIG. 1B) of at least a portion of the array of memory cells 104 are capable of being programmed to one of at least two target data states.

Row decode circuitry 108 and column decode circuitry 111 are provided to decode address signals. Address signals are received and decoded to access the array of memory cells 104. The memory device 130 also includes input/output (I/O) control circuitry 112 to manage input of commands, addresses and data to the memory device 130 as well as output of data and status information from the memory device 130. An address register 114 is in communication with the I/O control circuitry 112 and row decode circuitry 108 and column decode circuitry 111 to latch the address signals prior to decoding. A command register 124 is in communication with the I/O control circuitry 112 and local media controller 135 to latch incoming commands.

A controller (e.g., the local media controller 135 internal to the memory device 130) controls access to the array of memory cells 104 in response to the commands and generates status information for the external memory sub-system controller 115, i.e., the local media controller 135 is configured to perform access operations (e.g., read operations, programming operations and/or erase operations) on the array of memory cells 104. The local media controller 135 is in communication with row decode circuitry 108 and column decode circuitry 111 to control the row decode circuitry 108 and column decode circuitry 111 in response to the addresses.

The local media controller 135 is also in communication with a cache register 118 and a data register 121. The cache register 118 latches data, either incoming or outgoing, as directed by the local media controller 135 to temporarily store data while the array of memory cells 104 is busy writing or reading, respectively, other data. During a program operation (e.g., write operation), data can be passed from the cache register 118 to the data register 121 for transfer to the array of memory cells 104; then new data can be latched in the cache register 118 from the I/O control circuitry 112. During a read operation, data can be passed from the cache register 118 to the I/O control circuitry 112 for output to the memory sub-system controller 115; then new data can be passed from the data register 121 to the cache register 118. The cache register 118 and/or the data register 121 can form (e.g., can form at least a portion of) the page buffer 152 of the memory device 130. The page buffer 152 can further include sensing devices such as a sense amplifier, to sense a data state of a memory cell of the array of memory cells 104, e.g., by sensing a state of a data line connected to that memory cell. A status register 122 can be in communication with I/O control circuitry 112 and the local memory controller 135 to latch the status information for output to the memory sub-system controller 115.

The memory device 130 receives control signals at the memory sub-system controller 115 from the local media controller 135 over a control link 132. For example, the control signals can include a chip enable signal CE #, a command latch enable signal CLE, an address latch enable signal ALE, a write enable signal WE #, a read enable signal RE #, and a write protect signal WP #. Additional or alternative control signals (not shown) can be further received over control link 132 depending upon the nature of the memory device 130. In one embodiment, memory device 130 receives command signals (which represent commands), address signals (which represent addresses), and data signals (which represent data) from the memory sub-system controller 115 over a multiplexed input/output (I/O) bus 134 and outputs data to the memory sub-system controller 115 over I/O bus 134.

For example, the commands can be received over input/output (I/O) pins [7:0] of I/O bus 134 at I/O control circuitry 112 and can then be written into a command register 124. The addresses can be received over input/output (I/O) pins [7:0] of I/O bus 134 at I/O control circuitry 112 and can then be written into address register 114. The data can be received over input/output (I/O) pins [7:0] for an 8-bit device or input/output (I/O) pins [15:0] for a 16-bit device at I/O control circuitry 112 and then can be written into cache register 118. The data can be subsequently written into data register 121 for programming the array of memory cells 104.

In an embodiment, cache register 118 can be omitted, and the data can be written directly into data register 121. Data can also be output over input/output (I/O) pins [7:0] for an 8-bit device or input/output (I/O) pins [15:0] for a 16-bit device. Although reference can be made to I/O pins, they can include any conductive node providing for electrical connection to the memory device 130 by an external device (e.g., the memory sub-system controller 115), such as conductive pads or conductive bumps as are commonly used.

It will be appreciated by those skilled in the art that additional circuitry and signals can be provided, and that the memory device 130 of FIG. 1B has been simplified. It should be recognized that the functionality of the various block components described with reference to FIG. 1B may not necessarily be segregated to distinct components or component portions of an integrated circuit device. For example, a single component or component portion of an integrated circuit device could be adapted to perform the functionality of more than one block component of FIG. 1B. Alternatively, one or more components or component portions of an integrated circuit device could be combined to perform the functionality of a single block component of FIG. 1B. Additionally, while specific I/O pins are described in accordance with popular conventions for receipt and output of the various signals, it is noted that other combinations or numbers of I/O pins (or other I/O node structures) can be used in the various embodiments.

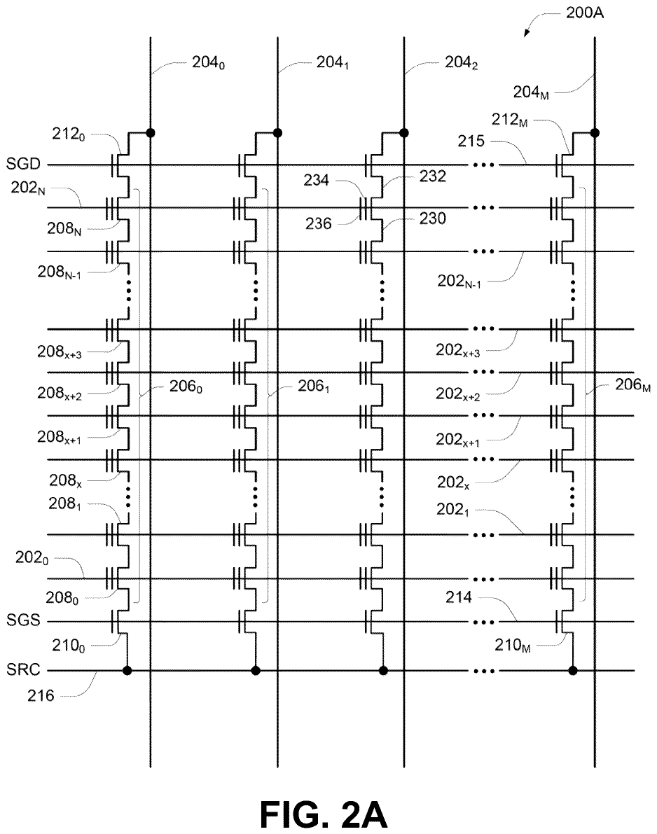

FIG. 2A-2B are schematics of portions of an array of memory cells 200A, such as a NAND memory array, as could be used in a memory of the type described with reference to FIG. 1B according to an embodiment, e.g., as a portion of the array of memory cells 104. Memory array 200A includes access lines, such as wordlines 202₀ to 202_{N}, and data lines, such as bitlines 204₀ to 204_{M}. The wordlines 202 can be connected to global access lines (e.g., global wordlines), not shown in FIG. 2A, in a many-to-one relationship. For some embodiments, memory array 200A can be formed over a semiconductor that, for example, can be conductively doped to have a conductivity type, such as a p-type conductivity, e.g., to form a p-well, or an n-type conductivity, e.g., to form an n-well.

Memory array 200A can be arranged in rows (each corresponding to a wordline 202) and columns (each corresponding to a bitline 204). Each column can include a string of series-connected memory cells (e.g., non-volatile memory cells), such as one of NAND strings 206₀ to 206_{M}. Each NAND string 206 can be connected (e.g., selectively connected) to a common source (SRC) 216 and can include memory cells 208₀ to 208_{N}. The memory cells 208 can represent non-volatile memory cells for storage of data. The memory cells 208 of each NAND string 206 can be connected in series between a select gate 210 (e.g., a field-effect transistor), such as one of the select gates 210₀ to 210_{M} (e.g., that can be source select transistors, commonly referred to as select gate source), and a select gate 212 (e.g., a field-effect transistor), such as one of the select gates 212₀ to 212_{M} (e.g., that can be drain select transistors, commonly referred to as select gate drain). Select gates 210₀ to 210_{M} can be commonly connected to a select line 214, such as a source select line (SGS), and select gates 212₀ to 212_{M} can be commonly connected to a select line 215, such as a drain select line (SGD). Although depicted as traditional field-effect transistors, the select gates 210 and 212 can utilize a structure similar to (e.g., the same as) the memory cells 208. The select gates 210 and 212 can represent a number of select gates connected in series, with each select gate in series configured to receive a same or independent control signal.

A source of each select gate 210 can be connected to common source 216. The drain of each select gate 210 can be connected to a memory cell 208₀ of the corresponding NAND string 206. For example, the drain of select gate 2100 can be connected to memory cell 208₀ of the corresponding NAND string 206₀. Therefore, each select gate 210 can be configured to selectively connect a corresponding NAND string 206 to the common source 216. A control gate of each select gate 210 can be connected to the select line 214.

The drain of each select gate 212 can be connected to the bitline 204 for the corresponding NAND string 206. For example, the drain of select gate 212₀ can be connected to the bitline 204₀ for the corresponding NAND string 206₀. The source of each select gate 212 can be connected to a memory cell 208_{N} of the corresponding NAND string 206. For example, the source of select gate 212₀ can be connected to memory cell 208_{N} of the corresponding NAND string 206₀. Therefore, each select gate 212 can be configured to selectively connect a corresponding NAND string 206 to the corresponding bitline 204. A control gate of each select gate 212 can be connected to select line 215.

The memory array 200A in FIG. 2A can be a quasi-two-dimensional memory array and can have a generally planar structure, e.g., where the common source 216, NAND strings 206 and bitlines 204 extend in substantially parallel planes. Alternatively, the memory array 200A in FIG. 2A can be a three-dimensional memory array, e.g., where NAND strings 206 can extend substantially perpendicular to a plane containing the common source 216 and to a plane containing the bitlines 204 that can be substantially parallel to the plane containing the common source 216.

Typical construction of memory cells 208 includes a data-storage structure 234 (e.g., a floating gate, charge trap, and the like) that can determine a data state of the memory cell (e.g., through changes in threshold voltage), and a control gate 236, as shown in FIG. 2A. The data-storage structure 234 can include both conductive and dielectric structures while the control gate 236 is generally formed of one or more conductive materials. In some cases, memory cells 208 can further have a defined source/drain (e.g., source) 230 and a defined source/drain (e.g., drain) 232. The memory cells 208 have their control gates 236 connected to (and in some cases form) a wordline 202.

A column of the memory cells 208 can be a NAND string 206 or a number of NAND strings 206 selectively connected to a given bitline 204. A row of the memory cells 208 can be memory cells 208 commonly connected to a given wordline 202. A row of memory cells 208 can, but need not, include all the memory cells 208 commonly connected to a given wordline 202. Rows of the memory cells 208 can often be divided into one or more groups of physical pages of memory cells 208, and physical pages of the memory cells 208 often include every other memory cell 208 commonly connected to a given wordline 202. For example, the memory cells 208 commonly connected to wordline 202_{N} and selectively connected to even bitlines 204 (e.g., bitlines 204₀, 204₂, 204₄, etc.) can be one physical page of the memory cells 208 (e.g., even memory cells) while memory cells 208 commonly connected to wordline 202_{N} and selectively connected to odd bitlines 204 (e.g., bitlines 204₁, 204₃, 204₅, etc.) can be another physical page of the memory cells 208 (e.g., odd memory cells).

Although bitlines 204₃-204₅ are not explicitly depicted in FIG. 2A, it is apparent from the figure that the bitlines 204 of the array of memory cells 200A can be numbered consecutively from bitline 204₀ to bitline 204_{M}. Other groupings of the memory cells 208 commonly connected to a given wordline 202 can also define a physical page of memory cells 208. For certain memory devices, all memory cells commonly connected to a given wordline can be deemed a physical page of memory cells. The portion of a physical page of memory cells (which, in some embodiments, could still be the entire row) that is read during a single read operation or programmed during a single programming operation (e.g., an upper or lower page of memory cells) can be deemed a logical page of memory cells. A block of memory cells can include those memory cells that are configured to be erased together, such as all memory cells connected to wordlines 202₀-202_{N} (e.g., all NAND strings 206 sharing common wordlines 202). Unless expressly distinguished, a reference to a page of memory cells herein refers to the memory cells of a logical page of memory cells. Although the example of FIG. 2A is discussed in conjunction with NAND flash, the embodiments and concepts described herein are not limited to a particular array architecture or structure, and can include other structures (e.g., SONOS, phase change, ferroelectric, etc.) and other architectures (e.g., AND arrays, NOR arrays, etc.).

FIG. 2B is another schematic of a portion of an array of memory cells 200B as could be used in a memory of the type described with reference to FIG. 1B, e.g., as a portion of the array of memory cells 104. Like numbered elements in FIG. 2B correspond to the description as provided with respect to FIG. 2A. FIG. 2B provides additional detail of one example of a three-dimensional NAND memory array structure. The three-dimensional NAND memory array 200B can incorporate vertical structures which can include semiconductor pillars. The NAND strings 206 can be each selectively connected to a bitline 204₀-204_{M} by a select transistor 212 (e.g., that can be drain select transistors, commonly referred to as select gate drain) and to a common source 216 by a select transistor 210 (e.g., that can be source select transistors, commonly referred to as select gate source). Multiple NAND strings 206 can be selectively connected to the same bitline 204. Subsets of NAND strings 206 can be connected to their respective bitlines 204 by biasing the select lines 215₀-215_{K} to selectively activate particular select transistors 212 each between a NAND string 206 and a bitline 204. The select transistors 210 can be activated by biasing the select line 214. In some embodiments, each sub-block or string of memory cells has a separate select line 214 from other sub-blocks or strings. In some embodiments, a pair of sub-blocks shares a select line 214. Each wordline 202 can be connected to multiple rows of memory cells of the memory array 200B. Rows of memory cells that are commonly connected to each other by a particular wordline 202 can collectively be referred to as tiers.

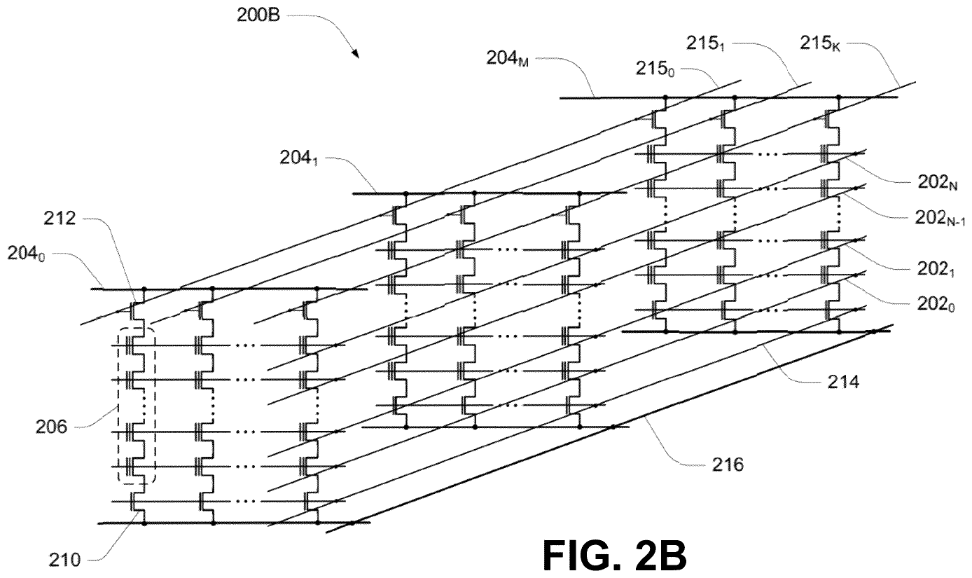

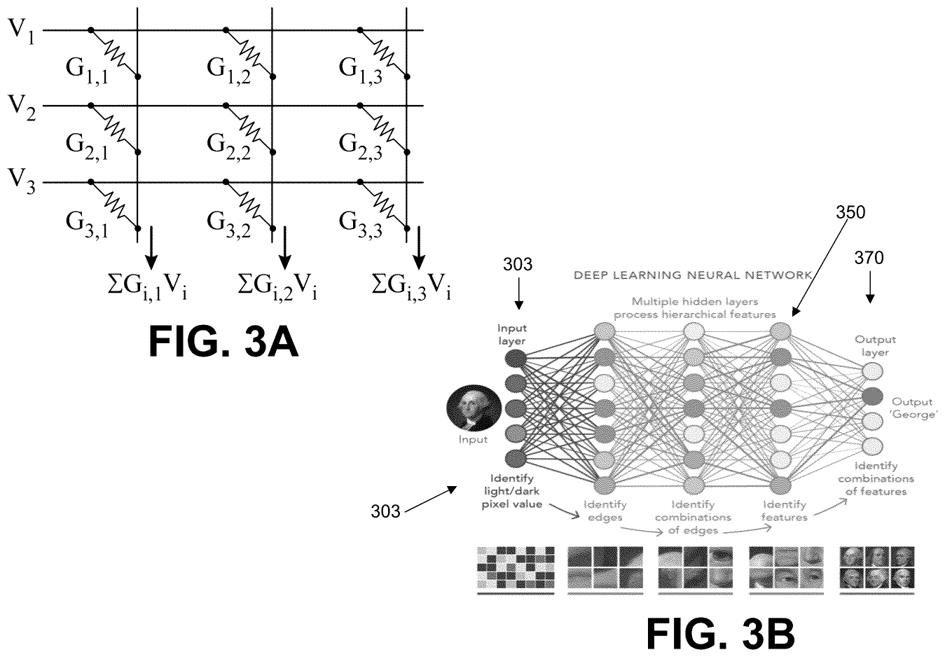

FIG. 3A is a schematic diagram of a simplified example of compute-in-memory (CIM) architecture for multiply and accumulate (MAC) calculations according to some embodiments. To obtain a matrix-vector product in a memory chip, the CIM architecture of FIG. 3A can be employed as an analog approach for a 3×3 matrix example. A matrix G is expressed by conductance of nine memory cells, Gi,j (i=1-3 and j=1-3), although those skilled in the art can appreciate that additional rows and columns of the matrix would include more memory cells to expand the size of matrix G. A vector V can be expressed by inputs on 3 bitlines, Vi (i=1-3). In various embodiments, a product of the N×M matrix and the N vector is generated with an N×M memory cell array and N bitlines. An analog MAC can then be defined as ΣGijVi, which value can be translated from currents or accumulated currents read out of memory strings of a memory array, as will be discussed in more detail.

FIG. 3B is a schematic diagram of a deep learning neural network 300, hidden layers of which can employ the CIM architecture of FIG. 3A the according to some embodiments. For example, a machine learning model could be embodied within the neural network 300, including an input layer 303 of features, followed by a series of hidden layers 350, followed by an output layer that identifies a combination of features as an output. Imagine, for example, the input to the neural network 300 is an image and the features provided through the input layer 303 include different lightness/darkness levels of pixels within the image. The various hidden layers 350 can include an identification of edges, an identification of combinations of edges, and ultimately, an identification of individual features. When those features are combined, a cogent output can identify what is depicted in the image. In disclosed embodiments of the CIM architecture, the hidden layers 350 of the neural network 300 can be expressed by weights calculated using multiple and accumulate calculations (or MACs) described herein. In many modern ML/AI applications, the hidden layers 350 carry out a significant number of MACs in order to update weights of the machine learning model represented by the neural network 300. Performing such MACs in hardware can significantly reduce the power consumption and can improve performance of ML/AI operations.

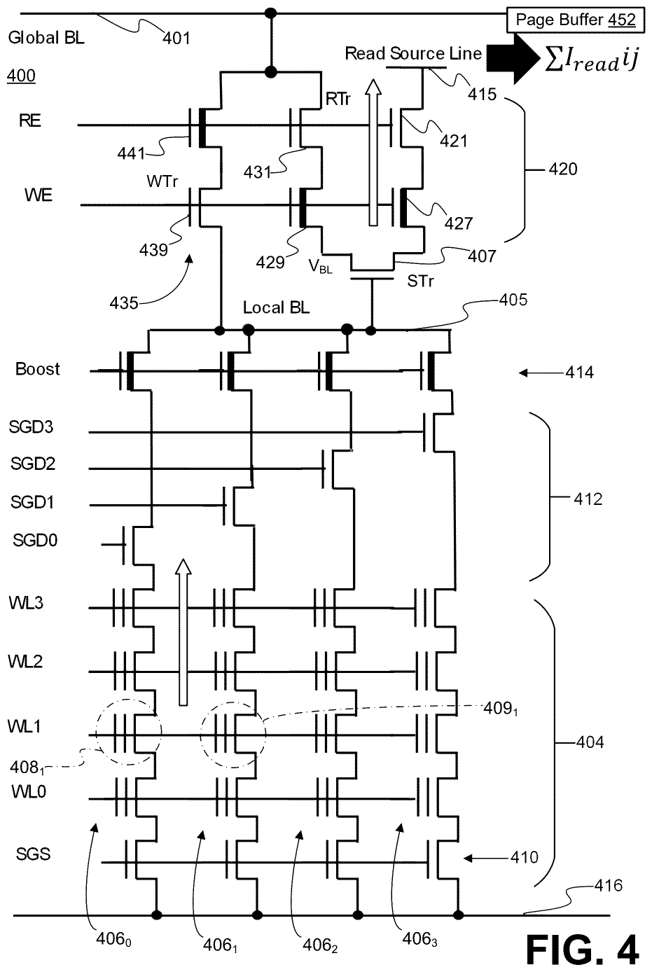

FIG. 4 is a partial schematic diagram of a portion 400 of a memory device (e.g., of the memory device 130) employing a CIM architecture that compensates for non-linearities caused by parasitic resistance, temperature change, and charge loss according to some embodiments. The portion 400 of the memory device 130 can include a memory array (such as the array of memory cells 104) having a plurality of sub-blocks, each composed of a plurality of strings 404 of memory cells coupled to a local bitline 405. In FIG. 4, the plurality of strings 404 include a first NAND string 4060, a second NAND string 406₁, a third NAND string 4062, and a fourth NAND string 4013, illustrated by way of example. The NAND strings 4060 to 4063 can also be coupled to source select transistors 410, which are in turn coupled to a common source 416 (or SRC), which in 3D NAND, can be a source plate layer, for example.

In some embodiments, the NAND strings 4060 to 4063 are coupled through respective ones of drain select transistors 412 coupled to the local bitline 405. Wordlines labeled as SGD0, SGD1, SGD2, SGD3 can be associated with the drain select transistors 412 that are respectively coupled to the NAND strings 4060 to 4063. In disclosed embodiments, a combination of the source select transistors 410 and the drain select transistors 412 can be referred to jointly as select line transistors for simplicity.

In embodiments, the portion 400 of the memory device 130 includes a set of boost transistors 414, each coupled between the local bitline 405 and a respective string of the plurality of strings 404. The boost transistors 414 can be enhanced-type transistors. In embodiments, wordlines labeled as WL0, WL1, WL2, WL3 are associated with memory cells of the plurality of strings 404 located progressively closer to the local bitline 405.

In some embodiments, the portion 400 of the memory device 130 includes a sense transistor 407 (or STr) having a gate terminal coupled with the local bitline 405 and a series of transistors 420 that includes a data read path between a read source line 415 and the sense transistor 407 and between the sense transistor 407 and a global bitline 401. For example, this read data path can be controlled in order to read data states out of memory cells of the plurality of strings 404. In embodiments, the global bitline 401 is also coupled with a page buffer 452. For example, current over the read source line 415 can be read out by the page buffer 452 or other read circuitry that is outside of the page buffer 452.

In some embodiments, the series of transistors 420 includes a first enhanced-type transistor 421 coupled with the read source line 415 and having a gate terminal coupled to a read-enable control line (RE). In embodiments, the series of transistors 420 includes a first depletion-type transistor 427 coupled between the first enhanced-type transistor 421 and a source of the sense transistor 407, the first depletion-type transistor having a gate terminal coupled with a write-enable control line (WE). In embodiments, the series of transistors 420 includes a second depletion-type transistor 429 coupled with a drain of the sense transistor 407 and has a gate terminal coupled to the write-enable control line (RE). In embodiments, the series of transistors 420 includes a second enhanced-type transistor 431 coupled between the second depletion-type transistor 429 and the global bitline 401, the second enhanced-type transistor having a gate terminal coupled with the read-enable control line (RE).

In some embodiments, the portion 400 of the memory device 130 further includes a second series of transistors 435 forming a write read path, e.g., to be enabled to bias the local bitline 405 when writing data to the plurality of strings 404 of memory cells. In embodiments, the second series of transistors 435 includes a third depletion-type transistor 441 coupled to the global bitline 401 in parallel with the series of transistors 420 and has a gate terminal also coupled with the read-enable control line (RE). In embodiments, the second series of transistors 435 includes a third enhanced-type transistor 439 (or write transistor, WTr) coupled between the third depletion-type transistor 441 and the local bitline 405 to form the aforementioned write data path. In embodiments, a gate terminal of the third enhanced-type transistor 441 is coupled with the write-enable control line (RE).

In at least some embodiments, the program manager 137 includes control logic coupled with the memory array, the series of transistors 420, the set of boost transistors 414, and the page buffer 452. In embodiments, each memory cell of the plurality of strings 404 has a Vₜ ranging within a low voltage (e.g., 0-1V or 1-1.2V) to express K digital bits (e.g., Gi,j in FIG. 3). In embodiments, the control logic can cause a particular voltage to be applied to a wordline (WL1) associated with a first memory cell 408₁ of a string of the plurality of strings 404 and to a boost wordline (“Boost”) associated with the set of boost transistors 414 to pull the local bitline 405 up to approximately the particular voltage. In embodiments, the control logic causes a high voltage to be applied to select line transistors and to wordlines associated with unselected memory cells of the string (e.g., applied to WL0, WL2, WL3). In such embodiments, the high voltage is at least twice the particular voltage (e.g., if the particular voltage is 2V, then the high voltage is at least 4V, but can be higher, which values are provided only by way of example, for purposes of explanation). The control logic can further cause a medium voltage to be applied to the common source 416 coupled to the memory array, where the medium voltage is between the particular voltage and the high voltage. The result, as mentioned, is that the local bitline 405 is charged up in a source-follower manner to about the particular voltage applied to the selected wordline and the boost wordline.

In some embodiments, the control logic causes a bitline voltage (V_{BL}) to be applied to the global bitline 401, e.g., where the bitline voltage represents a digital value. For example, the bitline voltage can be biased to range from 0-1V or 0-1.2V (or some similarly low voltage range) to express a plurality of digital bits (Vᵢ from FIG. 3). In embodiments, the control logic causes a current to be read out through the read source line 415 from the first memory cell 408₁, e.g., once at least the threshold voltage of the sense transistor 407 is supplied to the local bitline 405. In embodiments, an amount of the current depends on the digital value (from the global bitline voltage) and represents an analog multiplier of a MAC associated with a machine learning model, for example. Because the sense transistor 407 operates in a linear region, the current passing through to the read source line 415 can be expressed as:

$${I}_{read} = \frac{{W}^{′}}{{L}^{′}} {u}^{′} {{C}^{′}}_{o x} [ ( {V}_{b o o s t} + {V}_{WL 1} - {V}_{t} - {V}_{t n} ) {V}_{BL} - \frac{1}{2} {{V}_{BL}}^{2} ] , \qquad ( 1 )$$

where W′ and L′ are respectively the length and width of a gate of the first memory cell 408₁, μ′ is a constant, and C′ₒₓ is a capacitance based on an oxide layer of the first memory cell 408₁.

This I_{read} current can be aggregated over the read source line 415 as ΣI_{read}ij, or a total current. In embodiments, for example, the control logic causes the I_{read} current of Equation (1) to be concurrently combined with currents read out from other sub-blocks of the memory array to obtain the total current, e.g., where other such currents come from a string in another sub-block of the memory array. In embodiments, the control logic can further translate the total current to a MAC value for use in the machine learning model.

In embodiments, with additional reference to Equation (1), the I_{read} current is proportional to the bitline voltage (V_{BL}) multiplied by a combination of voltage values including: i) twice the particular voltage (e.g., V_{boost} and V_{WL1}); and ii) threshold voltages of the first memory cell (Vt) and of the sense transistor (Vtn). In embodiments, the bitline voltage (V_{BL}) is to range between a ground voltage and a maximum voltage that represents a plurality of digital bits.

As discussed, this model that employs the current Equation (1) may still be optimized by compensating for temperature dependency, charge loss, and Vt shifts in the threshold voltage (Vt) of the selected memory cell, e.g., the first memory cell 408₁. For example, compensation for the temperature dependency can be a way of changing the wordline voltage (V_{WL}) according to temperature. Further, compensation for charge loss can be performed by way of read level calibration. Additionally, compensation for Vₜ shifts can be performed via a corrective read, but as will be discussed, Vₜ shifts are complicated because they can depend on the Vt level of neighbor memory cells.

In various embodiments, however, these compensations for the Vt of the selected memory cell do not account for variations in the threshold voltage (Vtn) of the sense transistor 407, which can include temperature dependency, device-by-device variation, die-to-die variation, or wafer-to-wafer variation. The following extensions to the above approach can be performed in order to compensate for such Vtn variations.

In some embodiments, the control logic can also cause the local bitline 405 to be grounded and then to float. The control logic can cause, while the local bitline 405 is floating, a background current to be read out through the read source line 415, which can be expressed as Equation (2) due to the sense transistor 147 operating in the linear region.

$${I}_{str} = \frac{{W}^{′}}{{L}^{′}} {u}^{′} {{C}^{′}}_{o x} [ ( {V}_{b o o s t} - {V}_{t n} ) {V}_{BL} - \frac{1}{2} {{V}_{BL}}^{2} ] \qquad ( 2 )$$

This Iₛₜᵣ background current can be understood as a minimum current flow through the sense transistor 407 regardless of threshold voltage of the selected memory cell. In embodiments, determining the Iₛₜᵣ background current is performed during a separate read operation.

The control logic can further determine a difference between the Iread current and the background current (Iₛₜᵣ) to generate a compensated current (I_{diff}), which can be derived as illustrated across Equations (3), (4), (5). The derived value of I_{diff}, as can be observed in Equation (5), does not depend on the threshold voltage Vtn of the sense transistor 407, eliminating Vtn-based dependencies.

$${I}_{diff} = {I}_{read} - {I}_{str} \qquad ( 3 )$$

$$= \frac{{W}^{′}}{{L}^{′}} {u}^{′} {{C}^{′}}_{o x} [ ( {V}_{b o o s t} + {V}_{WL 1} - {V}_{t} - {V}_{t n} ) {V}_{BL} - \frac{1}{2} {{V}_{BL}}^{2} ] - \frac{{W}^{′}}{{L}^{′}} {u}^{′} {{C}^{′}}_{o x} [ ( {V}_{b o o s t} - {V}_{t n} ) {V}_{B L} - \frac{1}{2} {{V}_{BL}}^{2} ] \qquad ( 4 )$$

$$= \frac{{W}^{′}}{{L}^{′}} {u}^{′} {{C}^{′}}_{o x} ( {V}_{W L 1} - {V}_{t} ) {V}_{B L} \qquad ( 5 )$$

In embodiments, the control logic can further combine the compensated current with compensated currents of other sub-blocks of the memory array to determine a compensated MAC value. For example, the value of ΣI_{diff}ij can be equivalent (or convertible) to ΣGijVi with compensation.

In some embodiments that seek for still more-precise analog multiplier values, a full compensation scheme can be employed. For example, in some embodiments, a reference memory cell 409₁ can be selected that is next to (or a neighbor of) the selected memory cell 408₁ and associated with the same wordline, e.g., WL1 in this example. This reference memory cell 409₁ is expected to have a higher threshold voltage available as a reference Vt. For example, the Vt of the reference memory cell 409₁ could be as high as 1V, 1.2V, or the like at a lowest temperature.

Thus, in some embodiments, the control logic selects, after reading the first memory cell 408₁, a second memory cell 409₁ of the second string 406₁ of the plurality of strings 404. Thus, in this embodiment, the second memory cell 409₁ is also associated with the wordline (WL1). The control logic may then cause a reference current (I_{ref}) to be read out through the read source line 415 from the second memory cell 409₁. In embodiments, the reference current can be expressed as Equation (6). In embodiments, determining the I_{ref} current involves performing another read operation.

$${I}_{ref} = \frac{{W}^{′}}{{L}^{′}} {u}^{′} {{C}^{′}}_{o x} [ ( {V}_{b o o s t} + {V}_{WL 1} - {V}_{ref} - {V}_{tn} ) {V}_{BL} - \frac{1}{2} {{V}_{BL}}^{2} ] \qquad ( 6 )$$

In some embodiments, the control logic determines a difference between the I_{read} current and the reference current (I_{ref}) to generate a compensated current (I_{diff}), which can be derived as illustrated across Equations (7), (8), (9).

$${I}_{diff} = {I}_{read} - {I}_{str} \qquad ( 7 )$$

$$= \frac{{W}^{′}}{{L}^{′}} {u}^{′} {{C}^{′}}_{o x} [ ( {V}_{b o o s t} + {V}_{WL 1} - {V}_{t} - {V}_{t n} ) {V}_{BL} - \frac{1}{2} {{V}_{BL}}^{2} ] - \frac{{W}^{′}}{{L}^{′}} {u}^{′} {{C}^{′}}_{o x} [ ( {V}_{b o o s t} + {V}_{WL 1} - {V}_{ref} - {V}_{tn} ) {V}_{BL} - \frac{1}{2} {{V}_{BL}}^{2} ] \qquad ( 8 )$$

$$= \frac{{W}^{′}}{{L}^{′}} {u}^{′} {{C}^{′}}_{o x} ( {V}_{ref} - {V}_{t} ) {V}_{B L} . \qquad ( 9 )$$

The derived value of I_{diff}, as can be observed in Equation (9), does not depend on the threshold voltage Vtn of the sense transistor 407, eliminating Vtn-based dependencies. Further, temperature dependency and charge loss are automatically compensated because Vref and Vt would have the same behavior.

In embodiments, the control logic combines the compensated current with compensated currents of other sub-blocks of the memory array to determine a compensated MAC value. For example, the value of ΣI_{diff}ij can be equivalent (or convertible) to ΣGijVi with compensation. In some embodiments, with reference to Equation (9), the control logic can further, while training the machine learning model cause, via programming, a reference threshold voltage (V_{ref}) of the second memory cell 409₁ to be increased to increase a value of the compensated MAC value. In other or alternative embodiments, the control logic can cause, via programming, a threshold voltage (Vₜ) of the first memory cell 408₁ to be increased to reduce the compensated MAC value. In this way, by optimizing Gi,j, a ML/AI-based system can be improved.

In at least some alternative embodiments of generating the I_{read} current of Equation (1), the control logic causes a first voltage to be applied to the read-enable control line (RE), where the first voltage or a period of time the first voltage is applied represents a digital value. In such embodiments, the control logic causes a second voltage applied to the global bitline (e.g., the global bitline voltage) to be a constant voltage. This is possible because the RE voltage level can also be used to vary the bitline voltage (V_{BL}) that is delivered to the drain of the sense transistor 407, whether by changing the first voltage or by varying the time period the first voltage is applied to the RE control line associated with the third depletion-type transistor 441. Besides this variation, the previous approach to pull up the local bitline 405 and read out ΣI_{read}ij from multiple sub-blocks can remain the same.

Thus, in some embodiments, the first voltage ranges between a ground voltage (0V) and a maximum voltage (e.g., 1-2V or the like) that represents a plurality of digital bits, where the period of time that the first voltage is applied to RE remains constant. In the case that the voltage at RTr has 1V threshold voltage by ranging the RE potential level from 1V to 2V (assumed only by way of example), a drain voltage of sense transistor 407 changes from 0V to 1V. Thus, the global bitline 401 would have fixed value of 2V, 2.2V, or the like in this particular example. Only by way of example, if there are three digital bits, RE[7:0] can have 8 voltage levels such as approximately 1.000V, 1.125V, 1.250V, 1.375V, 1.500V, 1.625V, 1.750V, and 1.875V. In this way, the I_{read} current can be proportional to the first voltage multiplied by a combination of the voltage values previously discussed with reference to Equation (1).

In other embodiments, the first voltage is kept constant (e.g., at a fixed voltage level) to make the sense transistor 427 operate in a linear region with an appropriate bitline voltage (V_{BL}), e.g., 1V, 1.2V, or the like. In such embodiments, the period of time (t_{REH}) the fixed first voltage is applied to RE is varied, and the I_{read} current is integrated over the period of time, as is expressed in Equation (10), which current is proportional to the first voltage multiplied by a combination of voltage values discussed with reference to Equation (1).

$${\int }_{0}^{tREH} {I}_{r e a d} = {C}_{r e a d} = \frac{{W}^{′}}{{L}^{′}} {u}^{′} {{C}^{′}}_{o x} {t}_{REH} [ ( {V}_{b o o s t} + {V}_{WL 1} - {V}_{t} - {V}_{t n} ) {V}_{B L} - \frac{1}{2} {{V}_{BL}}^{2} ] \qquad ( 10 )$$

In embodiments, the period of time (t_{REH}) the first voltage is applied to the read-enable control line (RE) ranges between a plurality of time periods that represent a plurality of digital bits. In the case of representing 3 digital bits, only by way of example, t_{REH} [7:0] can be approximately 0 μsec, 1 μsec, 2 μsec, 3 μsec, 4 μsec, 5 μsec, 6 μsec, and 7 μsec.

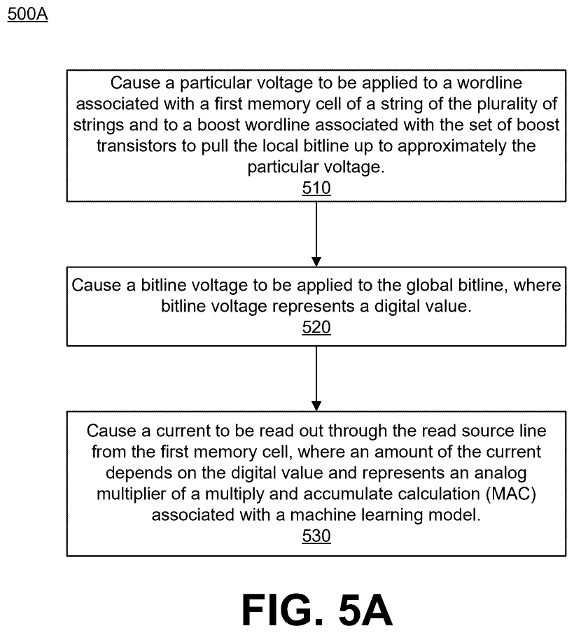

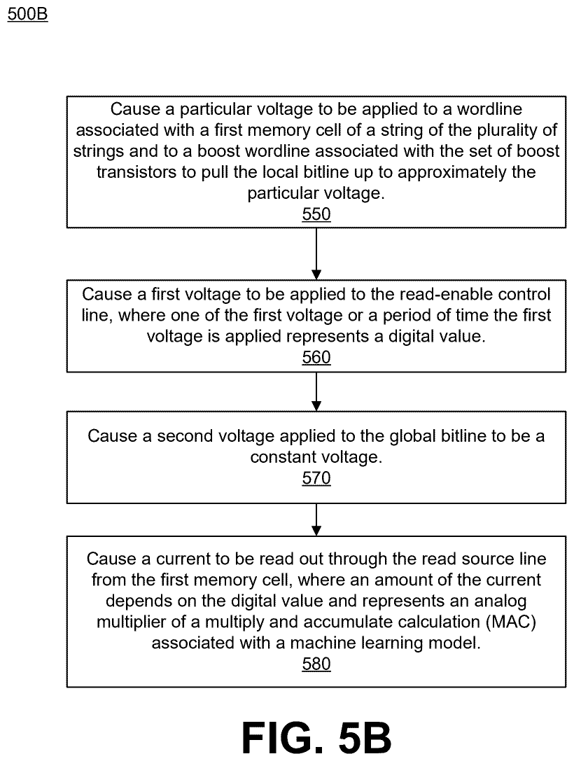

FIG. 5A is a flow diagram of an example method 500A of operating the memory device of FIG. 4 according to some embodiments. The method 500A can be performed by processing logic that can include hardware (e.g., processing device, circuitry, dedicated logic, programmable logic, microcode, hardware of a device, integrated circuit, etc.), software (e.g., instructions run or executed on a processing device), or a combination thereof. In some embodiments, the method 500A is performed by the local media controller 135 (e.g., control logic) of FIGS. 1A-1B, e.g., by the program manager 137, on a memory array that includes a plurality of memory cells electrically coupled to a plurality of wordlines and a plurality of bitlines. Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

At operation 510, the processing logic causes a particular voltage to be applied to a wordline associated with a first memory cell of a string of the plurality of strings and to a boost wordline associated with the set of boost transistors to pull the local bitline up to approximately the particular voltage.

At operation 520, the processing logic causes a bitline voltage to be applied to the global bitline, where the bitline voltage represents a digital value.

At operation 530, the processing logic causes a current to be read out through the read source line from the first memory cell. In embodiments, an amount of the current depends on the digital value and represents an analog multiplier of a multiply and accumulate calculation (MAC) associated with a machine learning model.

FIG. 5B is a flow diagram of an example method 500B of operating the memory device of FIG. 4 according to one or more varied embodiments. The method 500B can be performed by processing logic that can include hardware (e.g., processing device, circuitry, dedicated logic, programmable logic, microcode, hardware of a device, integrated circuit, etc.), software (e.g., instructions run or executed on a processing device), or a combination thereof. In some embodiments, the method 500B is performed by the local media controller 135 (e.g., control logic) of FIGS. 1A-1B, e.g., by the program manager 137, on a memory array that includes a plurality of memory cells electrically coupled to a plurality of wordlines and a plurality of bitlines. Although shown in a particular sequence or order, unless otherwise specified, the order of the processes can be modified. Thus, the illustrated embodiments should be understood only as examples, and the illustrated processes can be performed in a different order, and some processes can be performed in parallel.

At operation 550, the processing logic causes a particular voltage to be applied to a wordline associated with a first memory cell of a string of the plurality of strings and to a boost wordline associated with the set of boost transistors to pull the local bitline up to approximately the particular voltage.

At operation 560, the processing logic causes a first voltage to be applied to the read-enable control line, wherein one of the first voltage or a period of time the first voltage is applied represents a digital value.

At operation 570, the processing logic causes a second voltage applied to the global bitline to be a constant voltage.

At operation 580, the processing logic causes a current to be read out through the read source line from the first memory cell. In embodiments, an amount of the current depends on the digital value and represents an analog multiplier of a multiply and accumulate calculation (MAC) associated with a machine learning model.

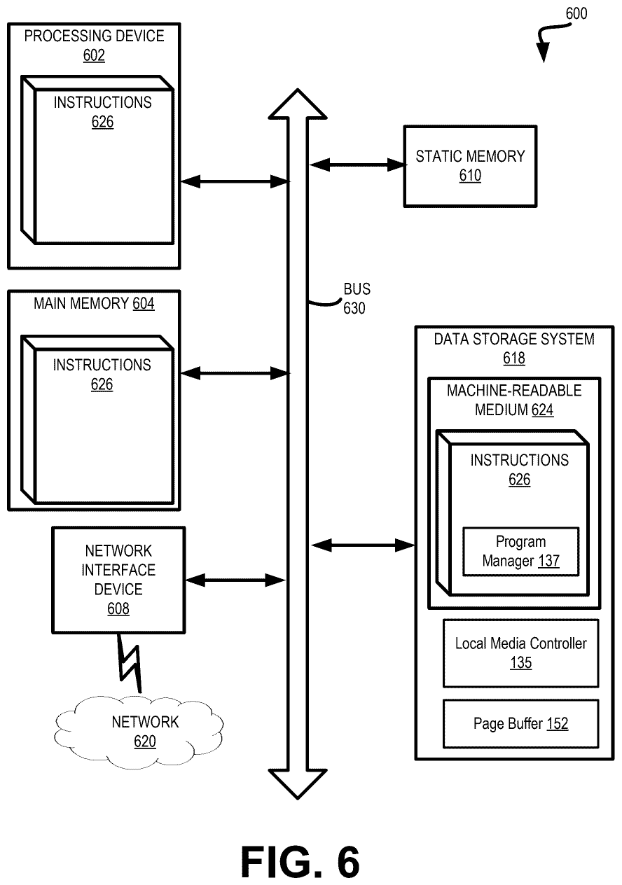

FIG. 6 illustrates an example machine of a computer system 600 within which a set of instructions, for causing the machine to perform any one or more of the methodologies discussed herein, can be executed. In some embodiments, the computer system 600 can correspond to a host system (e.g., the host system 120 of FIG. 1A) that includes, is coupled to, or utilizes a memory sub-system (e.g., the memory sub-system 110 of FIG. 1A) or can be used to perform the operations of a controller (e.g., to execute an operating system to perform operations corresponding to the memory sub-system controller 115 of FIG. 1A). In alternative embodiments, the machine can be connected (e.g., networked) to other machines in a LAN, an intranet, an extranet, and/or the Internet. The machine can operate in the capacity of a server or a client machine in client-server network environment, as a peer machine in a peer-to-peer (or distributed) network environment, or as a server or a client machine in a cloud computing infrastructure or environment.

The machine can be a personal computer (PC), a tablet PC, a set-top box (STB), a Personal Digital Assistant (PDA), a cellular telephone, a web appliance, a server, a network router, a switch or bridge, or any machine capable of executing a set of instructions (sequential or otherwise) that specify actions to be taken by that machine. Further, while a single machine is illustrated, the term “machine” shall also be taken to include any collection of machines that individually or jointly execute a set (or multiple sets) of instructions to perform any one or more of the methodologies discussed herein.

The example computer system 600 includes a processing device 602, a main memory 604 (e.g., read-only memory (ROM), flash memory, dynamic random access memory (DRAM) such as synchronous DRAM (SDRAM) or Rambus DRAM (RDRAM), etc.), a static memory 66 (e.g., flash memory, static random access memory (SRAM), etc.), and a data storage system 618, which communicate with each other via a bus 630.

Processing device 602 represents one or more general-purpose processing devices such as a microprocessor, a central processing unit, or the like. More particularly, the processing device can be a complex instruction set computing (CISC) microprocessor, reduced instruction set computing (RISC) microprocessor, very long instruction word (VLIW) microprocessor, or a processor implementing other instruction sets, or processors implementing a combination of instruction sets. Processing device 602 can also be one or more special-purpose processing devices such as an application specific integrated circuit (ASIC), a field programmable gate array (FPGA), a digital signal processor (DSP), network processor, or the like. The processing device 602 is configured to execute instructions 628 for performing the operations and steps discussed herein. The computer system 600 can further include a network interface device 612 to communicate over the network 620.

The data storage system 618 can include a machine-readable storage medium 624 (also known as a non-transitory computer-readable storage medium) on which is stored one or more sets of instructions 626 or software embodying any one or more of the methodologies or functions described herein, including those associated with the program manager 137. The data storage system 618 can further include the local media controller 135 and the page buffer 152 that were previously discussed. The instructions 628 can also reside, completely or at least partially, within the main memory 604 and/or within the processing device 602 during execution thereof by the computer system 600, the main memory 604 and the processing device 602 also constituting machine-readable storage media. The machine-readable storage medium 624, data storage system 618, and/or main memory 604 can correspond to the memory sub-system 110 of FIG. 1A.

In one embodiment, the instructions 626 include instructions to implement functionality corresponding to a controller (e.g., the memory sub-system controller 115 of FIG. 1A). While the machine-readable storage medium 624 is shown in an example embodiment to be a single medium, the term “machine-readable storage medium” should be taken to include a single medium or multiple media that store the one or more sets of instructions. The term “machine-readable storage medium” shall also be taken to include any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, optical media, and magnetic media.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm is here, and generally, conceived to be a self-consistent sequence of operations leading to a desired result. The operations are those requiring physical manipulations of physical quantities. Usually, though not necessarily, these quantities take the form of electrical or magnetic signals capable of being stored, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. The present disclosure can refer to the action and processes of a computer system, or similar electronic computing device, that manipulates and transforms data represented as physical (electronic) quantities within the computer system's registers and memories into other data similarly represented as physical quantities within the computer system memories or registers or other such information storage systems.

The present disclosure also relates to an apparatus for performing the operations herein. This apparatus can be specially constructed for the intended purposes, or it can include a general purpose computer selectively activated or reconfigured by a computer program stored in the computer. Such a computer program can be stored in a computer readable storage medium, such as, but not limited to, any type of disk including floppy disks, optical disks, CD-ROMs, and magnetic-optical disks, read-only memories (ROMs), random access memories (RAMs), EPROMS, EEPROMs, magnetic or optical cards, or any type of media suitable for storing electronic instructions, each coupled to a computer system bus.

The algorithms and displays presented herein are not inherently related to any particular computer or other apparatus. Various general purpose systems can be used with programs in accordance with the teachings herein, or it can prove convenient to construct a more specialized apparatus to perform the method. The structure for a variety of these systems will appear as set forth in the description below. In addition, the present disclosure is not described with reference to any particular programming language. It will be appreciated that a variety of programming languages can be used to implement the teachings of the disclosure as described herein.

The present disclosure can be provided as a computer program product, or software, that can include a machine-readable medium having stored thereon instructions, which can be used to program a computer system (or other electronic devices) to perform a process according to the present disclosure. A machine-readable medium includes any mechanism for storing information in a form readable by a machine (e.g., a computer). In some embodiments, a machine-readable (e.g., computer-readable) medium includes a machine (e.g., a computer) readable storage medium such as a read only memory (“ROM”), random access memory (“RAM”), magnetic disk storage media, optical storage media, flash memory devices, etc.

In the foregoing specification, embodiments of the disclosure have been described with reference to specific example embodiments thereof. It will be evident that various modifications can be made thereto without departing from the broader spirit and scope of embodiments of the disclosure as set forth in the following claims. The specification and drawings are, accordingly, to be regarded in an illustrative sense rather than a restrictive sense.

What is claimed is:

1. A memory device comprising:
a memory array comprising:
a sub-block comprising a plurality of strings of memory cells; and
a local bitline coupled with the plurality of strings;
a sense transistor having a gate terminal coupled with the local bitline;
a series of transistors that comprises a data read path between a read source line and the sense transistor and between the sense transistor and a global bitline;
a set of boost transistors, each coupled between the local bitline and a respective string of the plurality of strings; and
control logic coupled with the memory array, the series of transistors, and the set of boost transistors, the control logic to perform operations comprising:
causing a particular voltage to be applied to a wordline associated with a first memory cell of a string of the plurality of strings and to a boost wordline associated with the set of boost transistors to pull the local bitline up to approximately the particular voltage;
causing a bitline voltage to be applied to the global bitline, wherein the bitline voltage represents a digital value; and
causing a current to be read out through the read source line from the first memory cell, wherein an amount of the current depends on the digital value and represents an analog multiplier of a multiply and accumulate calculation (MAC) associated with a machine learning model.

2. The memory device of claim 1, wherein the current is proportional to the bitline voltage multiplied by a combination of voltage values comprising: i) twice the particular voltage; and ii) threshold voltages of the first memory cell and of the sense transistor, and wherein the bitline voltage is to range between a ground voltage and a maximum voltage that represents a plurality of digital bits.

3. The memory device of claim 1, wherein the operations further comprise:
causing the current to be concurrently combined with currents read out from other sub-blocks of the memory array to obtain a total current; and
translating the total current to a MAC value for use in the machine learning model.

4. The memory device of claim 1, wherein the operations further comprise:
causing a high voltage to be applied to select line transistors and to wordlines associated with unselected memory cells of the string, wherein the high voltage is at least twice the particular voltage; and
causing a medium voltage to be applied to a common source coupled to the memory array, the medium voltage being between the particular voltage and the high voltage.

5. The memory device of claim 1, wherein the series of transistors comprises:
a first enhanced-type transistor coupled with the read source line and having a gate terminal coupled to a read-enable control line;
a first depletion-type transistor coupled between the first enhanced-type transistor and a source of the sense transistor, the first depletion-type transistor having a gate terminal coupled with a write-enable control line;
a second depletion-type transistor coupled with a drain of the sense transistor and having a gate terminal coupled to the write-enable control line; and
a second enhanced-type transistor coupled between the second depletion-type transistor and the global bitline, the second enhanced-type transistor having a gate terminal coupled with the read-enable control line.

6. The memory device of claim 5, further comprising:
a third depletion-type transistor coupled to the global bitline in parallel with the series of transistors and having a gate terminal also coupled with the read-enable control line; and
a third enhanced-type transistor coupled between the third depletion-type transistor and the local bitline to form a write data path, wherein a gate terminal of the third enhanced-type transistor is coupled with the write-enable control line.

7. The memory device of claim 1, wherein the operations further comprise:
causing the local bitline to be grounded and then to float;
causing, while the local bitline is floating, a background current to be read out through the read source line;
determining a difference between the current and the background current to generate a compensated current; and
combining the compensated current with compensated currents of other sub-blocks of the memory array to determine a compensated MAC value.

8. The memory device of claim 1, wherein the operations further comprise:
selecting, after reading the first memory cell, a second memory cell of a second string of the plurality of strings, wherein the second memory cell is also associated with the wordline;
causing a reference current to be read out through the read source line from the second memory cell;
determining a difference between the current and the reference current to generate a compensated current; and
combining the compensated current with compensated currents of other sub-blocks of the memory array to determine a compensated MAC value.

9. The memory device of claim 8, wherein the operations further comprise, while training the machine learning model, one of:
causing, via programming, a reference threshold voltage of the second memory cell to be increased to increase a value of the compensated MAC value; or
causing, via programming, a threshold voltage of the first memory cell to be increased to reduce the compensated MAC value.

10. A method of operating a memory device comprising a memory array comprising a sub-block having a plurality of strings of memory cells and a local bitline coupled with the plurality of strings, a sense transistor have a gate terminal coupled with the local bitline, a series of transistors comprising a data read path between a read source line and the sense transistor and between the sense transistor and a global bitline, a set of boost transistors, each coupled between the local bitline and a respective string, and control logic, wherein the method of operating the memory device comprises:
causing a particular voltage to be applied to a wordline associated with a first memory cell of a string of the plurality of strings and to a boost wordline associated with the set of boost transistors to pull the local bitline up to approximately the particular voltage;
causing a bitline voltage to be applied to the global bitline, wherein the bitline voltage represents a digital value; and
causing a current to be read out through the read source line from the first memory cell, wherein an amount of the current depends on the digital value and represents an analog multiplier of a multiply and accumulate calculation (MAC) associated with a machine learning model.

11. The method of claim 10, wherein the current is proportional to the bitline voltage multiplied by a combination of voltage values comprising: i) twice the particular voltage; and ii) threshold voltages of the first memory cell and of the sense transistor, further comprising causing the bitline voltage to range between a ground voltage and a maximum voltage that represents a plurality of digital bits.

12. The method of claim 10, further comprising:
causing the current to be concurrently combined with currents read out from other sub-blocks to obtain a total current; and
translating the total current to a MAC value for use in the machine learning model.

13. The method of claim 10, further comprising:
causing a high voltage to be applied to select line transistors and to wordlines associated with unselected memory cells of the string, wherein the high voltage is at least twice the particular voltage; and
causing a medium voltage to be applied to a common source coupled to the memory array, the medium voltage being between the particular voltage and the high voltage.

14. The method of claim 10, further comprising:
causing the local bitline to be grounded and then to float;
causing, while the local bitline is floating, a background current to be read out through the read source line;
determining a difference between the current and the background current to generate a compensated current; and
combining the compensated current with compensated currents of other sub-blocks of the memory array to determine a compensated MAC value.

15. The method of claim 10, further comprising:
selecting, after reading the first memory cell, a second memory cell of a second string of the plurality of strings, wherein the second memory cell is also associated with the wordline;
causing a reference current to be read out through the read source line from the second memory cell;
determining a difference between the current and the reference current to generate a compensated current; and
combining the compensated current with compensated currents of other sub-blocks of the memory array to determine a compensated MAC value.

16. The method of claim 15, further comprising, while training the machine learning model, one of:
causing, via programming, a reference threshold voltage of the second memory cell to be increased to increase a value of the compensated MAC value; or
causing, via programming, a threshold voltage of the first memory cell to be increased to reduce the compensated MAC value.

17. A memory device comprising:
a memory array comprising:
a sub-block comprising a plurality of strings of memory cells; and
a local bitline coupled with the plurality of strings;
a sense transistor having a gate terminal coupled with the local bitline;
a series of transistors that comprises a data read path between a read source line and the sense transistor and between the sense transistor and a global bitline, wherein transistors of the series of transistors that are coupled to the read source line and the global bitline have gate terminals coupled with a read-enable control line;
a set of boost transistors, each coupled between the local bitline and a respective string of the plurality of strings; and
control logic coupled with the memory array, the series of transistors, and the set of boost transistors, the control logic to perform operations comprising:
causing a particular voltage to be applied to a wordline associated with a first memory cell of a string of the plurality of strings and to a boost wordline associated with the set of boost transistors to pull the local bitline up to approximately the particular voltage;
causing a first voltage to be applied to the read-enable control line, wherein one of the first voltage or a period of time the first voltage is applied represents a digital value;
causing a second voltage applied to the global bitline to be a constant voltage; and
causing a current to be read out through the read source line from the first memory cell, wherein an amount of the current depends on the digital value and represents an analog multiplier of a multiply and accumulate calculation (MAC) associated with a machine learning model.

18. The memory device of claim 17, wherein the current is proportional to the first voltage multiplied by a combination of voltage values comprising: i) twice the particular voltage; and ii) threshold voltages of the first memory cell and of the sense transistor, and wherein the first voltage is to range between a ground voltage and a maximum voltage that represents a plurality of digital bits.

19. The memory device of claim 17, wherein the current is integrated over the period of time and is proportional to the first voltage multiplied by a combination of voltage values comprising: i) twice the particular voltage; and ii) threshold voltages of the first memory cell and of the sense transistor, and wherein the period of time the first voltage is applied to the read-enable control line is to range between a plurality of time periods that represent a plurality of digital bits.

20. The memory device of claim 17, wherein the operations further comprise:
causing the current to be concurrently combined with currents read out from other sub-blocks of the memory array to obtain a total current; and
translating the total current to a MAC value for use in the machine learning model.
